(19) United States
(12) Patent Application Publication
(10) Pub. No.: US 2023/0184045 A1
(43) Pub. Date: Jun. 15, 2023

(54) DEVICE AND METHOD FOR DIAGNOSING THE RISK OF INSUFFICIENT HOLE CLEANING PROBLEM

(71) Applicant: Yangtze University, Wuhan (CN)

(72) Inventors: FEIFEI ZHANG, Wuhan (CN); Tao Peng, Wuhan (CN); Xi Wang, Wuhan (CN); Yidi Wang, Wuhan (CN); Xueying Wang, Wuhan (CN); Yibing Yu, Wuhan (CN); Kai Wei, Wuhan (CN)

(21) Appl. No.: 17/669,394

(22) Filed: Feb. 11, 2022

(30) Foreign Application Priority Data
Dec. 15, 2021 (CN) 2021115373635

(51) Int. Cl. E21B 21/08; E21B 47/047

(52) U.S. Cl. CPC E21B 21/08; E21B 47/047

(57) ABSTRACT

The present disclosure provides a device and method for diagnosing risk of insufficient hole cleaning problem during drilling wells. The method includes obtaining the measured pressure via several measuring points, and obtaining actually measured value of each measuring point; calculate the theoretical pressure at each measuring points by using the real-time operational data as inputs, evaluating a hole cleaning condition by applying a difference between a theoretical pressure drop and a measured pressure drop to a developed pressure driven hole cleaning model, which gives the risk of insufficient hole cleaning problems and problematic locations. The theoretical pressure drop between two adjacent measurement points along wellbore includes the pressure drop caused by friction effect and hydrostatic effect. However, suspended cuttings in actual drilling fluid may significantly change the pressure drop along wellbore.

### TECHNICAL FIELD

The present disclosure relates to a field of drilling construction technology, in particular to a device and method for diagnosing a risk of insufficient hole cleaning problem with along string measurements (ASMs).

### BACKGROUND

Insufficient hole-cleaning has been a major concern for several decades in drilling industry (refer to Chinese invention patent, No. CN201910119287.2), which causes several drilling problems, such as pack-off, stuck pipe and ECD related problems. Furthermore, a major challenge for real-time downhole condition monitoring is uncertainties of input parameters for drilling models. The uncertainties among these parameters increase as the well depth increases. Even, by enlarging the well length, accuracy of the drilling models may be decreased by the well length grows uncertainties of input parameters.

In prior art, it is difficult to obtain a concentration of suspended cuttings in drilling fluid, which makes it difficult to determine the risk of insufficient hole cleaning problem.

### SUMMARY

In view of this, it is necessary to provide a device and method for diagnosing risk insufficient hole cleaning with ASMs, which is configured to solve a technical problem in prior art that it is difficult to obtain a concentration of suspended cuttings in drilling fluid, and thus it is inconvenient to determine the risk of insufficient hole cleaning problem.

For above purposes, the present disclosure provides a method for diagnosing the risk insufficient hole cleaning with ASMs, including:

obtaining measured pressure via each measuring point. Calculating a theoretical pressure drop at each measuring point by using a real-time operational data as input;

obtaining theoretical pressure drop of two adjacent measuring point on a wellbore; and

evaluating a hole cleaning condition by applying difference between the theoretical pressure drop and the measured pressure drop.

According to the theoretical pressure drop of each well section, the theoretical pressure drop of two adjacent measuring points on the wellbore is obtained in some embodiments, specifically including:

dividing the wellbores into several sections;

obtaining construction parameters and shape parameters of each well section, and the construction parameters include bit depth, well depth, drilling fluid density, average drilling fluid velocity, etc.

respectively calculating the theoretical pressure drop of each section according to the construction parameters and the shape parameters; and

obtaining the theoretical pressure drop of the two adjacent measuring points on the wellbore.

Furthermore, calculating the theoretical pressure drop of each well section according to the construction parameters and the shape parameters of each well section, specifically including:

according to the construction parameters and the shape parameters of each well section, respectively calculating the pressure drop caused by gravity effect of each well section;

according to the construction parameters and the shape parameters of each well section, respectively calculating the pressure drop caused by friction effect of each well section; and

according to the pressure drop caused by the gravity effect and the friction effect, obtaining the theoretical pressure drop of each well section.

Furthermore, according to the construction parameters and the shape parameters of each well section, respectively calculating the theoretical pressure drop caused by the gravity effect, specifically including:

according to the construction parameters and the shape parameters of each well section, using a hydrostatic pressure method to calculate the pressure drop caused by the gravity effect.

In some embodiments, according to the construction parameters and the shape parameters of each well section, respectively calculating the theoretical pressure drop caused by the friction effect, specifically including:

respectively determining a flow state of drilling fluid in each well section;

if the flow state of drilling fluid in the certain section is laminar flow, the pressure drop caused by the friction effect may be calculated according to a laminar flow annular air friction pressure loss model; and

if the flow state of the drilling fluid in the certain section is turbulent, the pressure drop caused by the friction effect may be calculated according to the turbulent annular air friction pressure loss formula.

In some embodiments, a pressure loss of the fluid flow in wellbore is obtained if there is turbulent flow:

$$Δ p = 2 {f}_{f} \frac{L}{{D}_{e}} ρ {v}^{2}$$

where f_{f} is a friction factor, L is a wellbore length, v is a mean flow velocity, ρ is a fluid density, and Dₑ is an equivalent diameter of annulus.

Furthermore, the theoretical pressure drop of each well section is obtained according to the pressure drop caused by the gravity effect and the friction effect, specifically:

the theoretical pressure drop of each well section is equal to a sum of the pressure drop caused by the friction effect and the pressure drop caused by the gravity effect.

Furthermore, determining the risk of insufficient hole clean problem according to the theoretical pressure drop and the measure pressure drop, specifically including:

according to the theoretical pressure drop and the actual measured pressure drop of adjacent measuring points on the wellbore, reversing a cutting concentration; and

determining the risk of insufficient hole clean problem according to the predicted cutting concentration.

The present disclosure provides a device for diagnosing the risk of insufficient hole cleaning problem, including a processing unit and a memory unit. The memory unit stores computer program, and the computer program is executed by the processing unit to achieve the method for diagnosing the risk of insufficient hole clean problem.

The present disclosure provides a system for diagnosing the risk of insufficient hole cleaning problem, including several along string measurement devices (ASMs) of using to measure annulus pressure in each measurement point.

### BRIEF DESCRIPTION OF DRAWINGS

FIG. 1 is a workflow schematic diagram of a method for diagnosing a risk of insufficient hole cleaning problem according to one embodiment of the present disclosure.

FIG. 2 is a structural schematic diagram of a drilling system according to one embodiment of the present disclosure.

FIG. 3 is a structural schematic diagram of a pressure measurement device of FIG. 2.

FIG. 4 is a structural schematic diagram of an annulus measurement port of FIG. 3.

FIG. 5 is a workflow schematic diagram of step S2 of FIG. 1.

FIG. 6 is a workflow schematic diagram of step S23 of FIG. 5.

FIG. 7 is a workflow schematic diagram of step S232 of FIG. 6.

FIG. 8 is a workflow schematic diagram of a relationship between prediction results and measurements, also called the update function, while using the AI tuning algorithm.

FIG. 9 is a workflow schematic diagram of step S3 of FIG. 1.

In the drawings: 1—drilling system, 2—along string measurement device components, 3—section of along string measurement device, 11—controller, 12—processing unit, 13—mud pump, 14—choke value, 15—along string measurement device, 151—communication port, 152—electronic section, 153—transducer section, 154—annular pressure port, 1541—sensitive port, 1542—internal gauge, 1543—annular gauge. 16—drillstring, 17—drill bit.

It should be understood, however, that the specific embodiments given in the drawings and detailed description do not limit the disclosure. On the contrary, they provide the foundation for one of ordinary skill to discern the alternative forms, equivalents, and modifications that are encompassed together with one or more of the given embodiments in the scope of the appended claims.

### DETAILED DESCRIPTION

The preferred embodiments of the present disclosure will be described in detail with the accompanying drawings. The accompanying drawings is one part of this application and are used together with the implementation examples to explain the principle of the present disclosure.

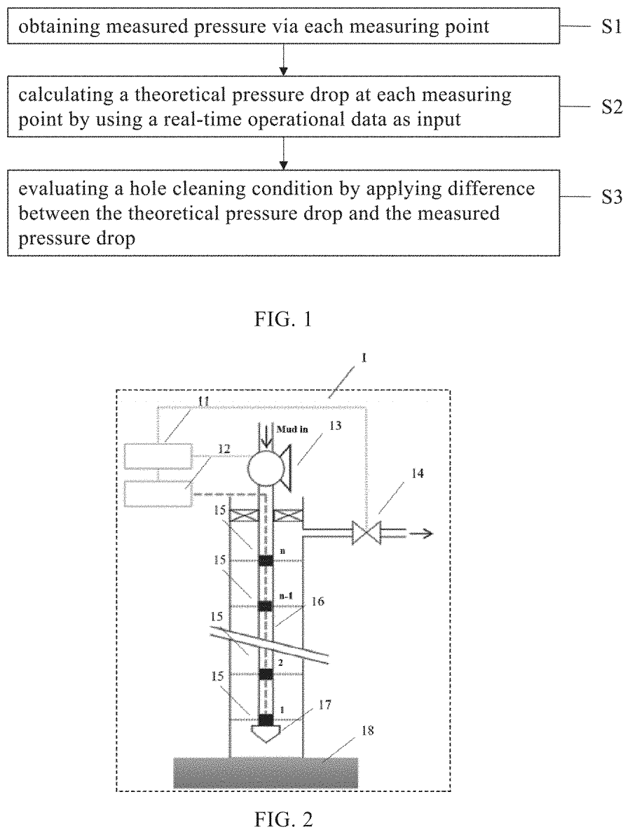

As illustrated in FIG. 1, the present disclosure provides a device and method for diagnosing the risk of insufficient hole cleaning problem with along string measurements (ASMs), including:

S1, obtaining the measured pressure via each measuring point.

S2, calculating the theoretical pressure at each measuring points by using the real-time operational data as input. Specifically, the theoretical pressure drop includes friction effect and hydrostatic effect.

S3, evaluating the hole cleaning condition by applying difference between the real-time predicted and measured pressure.

The beneficial effects of present disclosure is: the theoretical pressure drop between two adjacent measurement points along wellbore includes the pressure drop caused by the friction effect and the hydrostatic effect. But, the suspended cuttings in actual drilling fluid may significantly change the pressure drop along wellbore. If there are a lot of cuttings, there will be a significant difference between the calculated and the measured pressure drop. Therefore, by comparing the relationship between the theoretical and the measured pressure drop, which may be configured to evaluate the insufficient hole cleaning problems and the problematic locations for better drilling safety.

In step S1, in order to facilitate the acquisition of the measured pressure from each measurement point, the present disclosure provides a diagnose system of insufficient hole cleaning problems, including: the diagnose system with ASMs.

As illustrated in FIG. 2. The diagnose system with ASMs, which include a controller 11, a processing unit 12, a mud pump 13, a choke value 14, along string measurement device 15, drillstring 16, drill bit 17, reservoir 18, are configured to measure the wellbore annulus pressure at different positions. The controller 11 is the part that controls the different components of the diagnose system. The processing unit 12 is the decision making component of the main diagnose system, and it takes this inputs (such as real-time pressure value from ASM 2, wellbore trajectory, wellbore structure, and drill string design) and evaluate the cuttings concentration distribution along the wellbore and the insufficient hole cleaning risk index. The processing unit 12 contains the hardware system (such as computer, sever) and the hole cleaning evaluation algorithms, which includes hybrid drilling hydraulic model, pressure-driven hole cleaning model, hole cleaning risk evaluation. The mud pump 13 is configured to transfer configured drilling mud to the entire circulation flowing test area automatically by controller 11. The choke value 14 is configured to ensure the whole diagnose system pressure balance. Also, it is controlled by controller 11. These ASMs 15 are mainly configured to detect the annulus pressure in real-time and transmit the processed signal to processing unit 12 for further operation. The drill bit 18 for the present disclosure is this passage of drilling fluid from drillstring to the annulus and break rock. The reservoir 19 is a rock formation that have connected pores in which oil and gas may be stored and leached.

During the specific implementation, the well structure, drilling tool assembly design, drilling fluid configuration, mud pump performance parameters and temperature and pressure conditions that should be reached before the experiment; The mud pump 13 starts to inject the drilling fluid into the drillstring 16 after the flow signal is given by the controller 11. And then this entry diagnose unit reach dynamic cycle, open the choke value 14. These ASMs 15 are converted into electrical signals and returned to the processing unit 12, and the pressure signal begin to change. While everywhere along this drillstring 16 is filled with fluid and reaches dynamic equilibrium, the entire test system now constitutes a complete mud circulation loop.

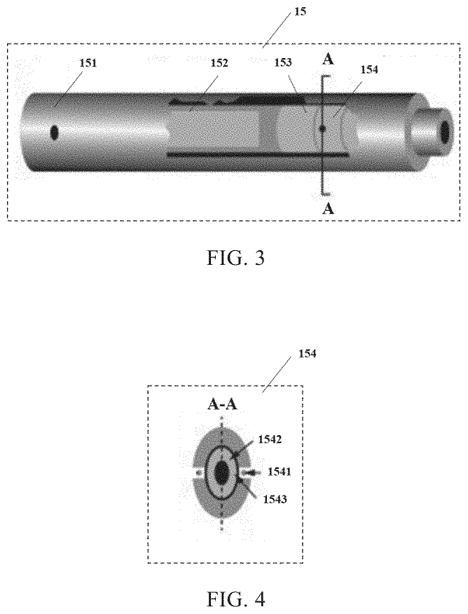

As illustrated in FIGS. 3 and 4, the present disclosure provides a diagnose system of insufficient hole cleaning a problem that these real-time pressure data is obtained by the ASM, including: along string measurement device 15.

The ASM component 15, which include a communication port 151, an electronic section 152 a transducer section 153 and an annular pressure port 1544, are configured to record the measured pressure value and transmit signal. The section of ASM indicate the detail of how the annular pressure port collect pressure values at annular nodes. The electronic section 152 contains several components like terminal, connector, power supply, etc. for whole system stability. The transducer section 153 is composed of three parts: sensitive element, conversion element and signal conditioning conversion circuit. The sensitive element may feel or respond directly to the measured value; The conversion element may convert measured value sensed or responded into electrical signal suitable for transmission. Because the output signal of the sensor is generally very weak, the output signal needs signal conditioning and conversion, amplification, operation and modulation before display or control. The annular pressure port 154 contains an internal gauge 1542, annular gauge 1543 and two ports 1541. It may directly collect pressure values at annular nodes, continuously measure and record pressure changes.

After the real-time annular pressure value is sampled by the sensitive element, and the corresponding frequency signal is output. Then measurement counting module is configured to calculate value corresponding of pressure and output. The calculated value is input to the processor for pressure value conversion, and is compensated according to the zero drift and temperature drift characteristics of sensitive element. The processed data is stored in RAM, then the communication circuit transits measured data to the system bus according to the communication protocol and control timing sequence.

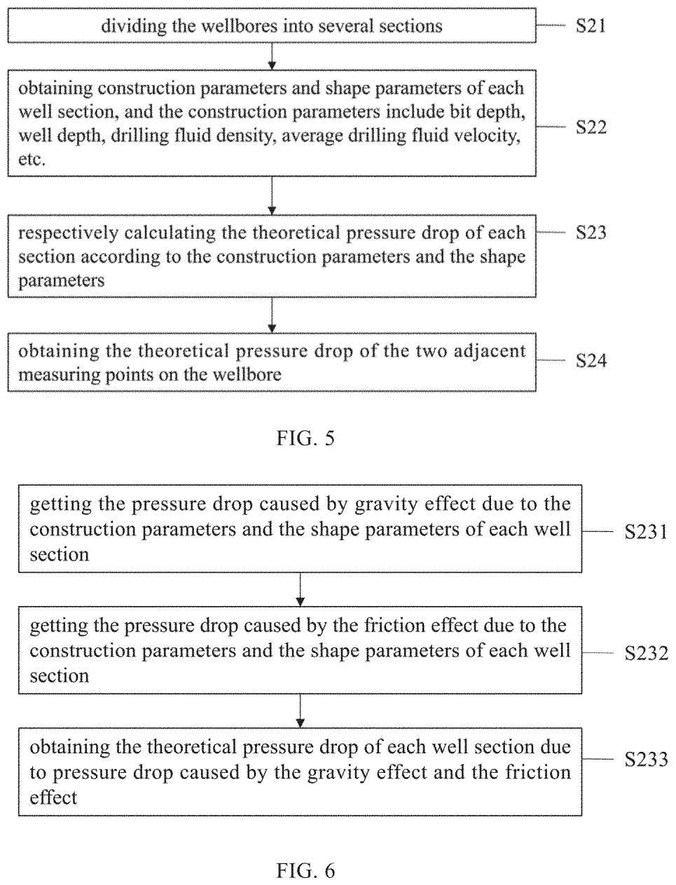

As illustrated in FIG. 5, the S2 includes:

S21, dividing wellbore information into several sections;

S22, obtaining the construction parameters and the shape parameters of each well section, wherein the parameters include bit depth, well depth, drilling fluid density, average drilling fluid velocity, etc.;

S23, calculating the theoretical pressure drop of each section rely on the construction parameters and its shape size;

S24, obtaining the theoretical pressure drop of two adjacent measuring points on the wellbore. Specifically, the theoretical pressure drop is equal to the sum of the gravity effect and the friction effect.

Among them, refer to FIG. 6, step S23 specifically includes:

S231, getting the pressure drop caused by gravity effect due to the construction parameters and the shape parameters of each well section. It is worth noting that pressure drop caused by gravity effect is an existing technology, which will not be repeated here;

S232, getting the pressure drop caused by the friction effect due to the construction parameters and the shape parameters of each well section;

S233, obtaining the theoretical pressure drop of each well section due to pressure drop caused by the gravity effect and the friction effect.

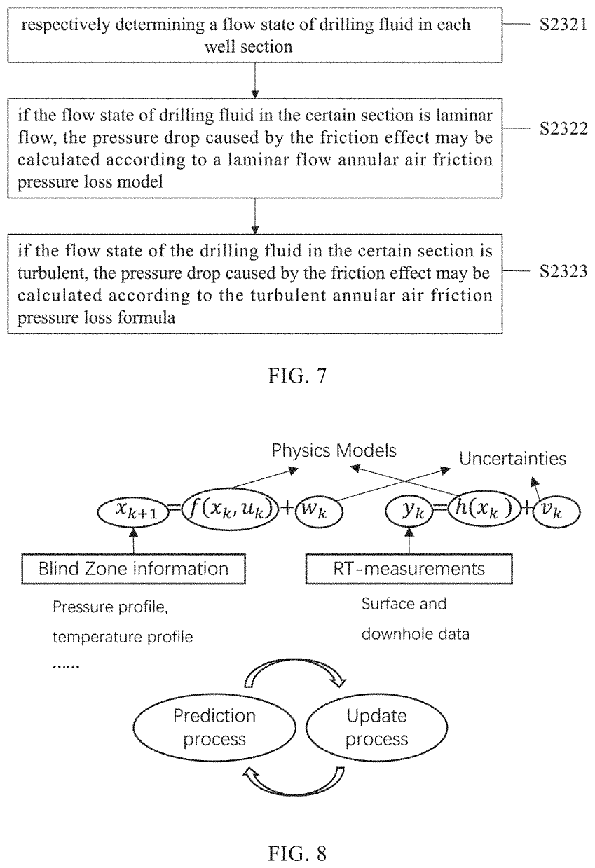

Among them, refer to FIG. 7, step S232 specifically includes:

S2321, determining the flow pattern of drilling fluid in each well section;

S2322, if the flow state of drilling fluid in certain section is laminar flow, the pressure drop caused by the friction effect may be calculated according to the laminar flow annular air friction pressure loss model. Refer to Table 1 the mathematical models to calculate frictional pressure loss in wellbore for laminar flow are summarized:

Table 1 Annulus friction pressure loss model in laminar flow

S2323, for turbulent flow, the pressure loss of the fluid flow in wellbore is obtained:

$$Δ p = 2 {f}_{f} \frac{L}{{D}_{e}} ρ {v}^{2}$$

where f_{f} is the friction factor, L is the wellbore length, v is the mean flow velocity, ρ is the fluid density, and De is the equivalent diameter of the annulus. There are several commonly used friction models in the industry, which are summarized:

| Friction factor model | Source |
|---|---|
| $\frac{1}{\sqrt{{f}_{f}}} = \frac{4}{{N}^{0.75}} log ( {N}_{R e} {f}_{f}^{1 - \frac{N}{2}} ) - \frac{0.4}{{N}^{1.2}}$ | Dodge & Metzner, 1959 |
| $\frac{1}{\sqrt{f}} = \frac{2.69}{{n}^{′}} - 2.95 + \frac{4.53}{{n}^{′}} lg [ {Re}_{g} {f}^{( 2 - {n}^{′} )} ] + 0.68 ( \frac{5 {n}^{′} - 8}{{n}^{′}} )$ | Clapp, 1961 |
| $\frac{1}{\sqrt{2 {f}_{f}}} = - 0.86 ln ( \frac{\frac{{d}_{c}}{{d}_{hyd}}}{3.7} + \frac{2.51}{{N}_{R e} \sqrt{2 {f}_{f}}} )$ | Televantos, 1979 |
| ${f}_{f} = 0.966 ( {N}_{R e}^{- 1.7} {{N}^{2.36} ( \frac{{d}_{c}}{{d}_{hyd}} )}^{- 2.35} )$ | Martins, 2001 |

The advantage of calculating pressure drop separately in the present patent is that different pressure drop models may be configured for each interval well segment. For each well segment, historical data were configured to establish several suitable hydraulic models. These models may better match the ASMs' input to estimate current pressure drop for each well segment, also better describe the actual hole pressure drop profile. With given boundary conditions at both sides, the more consistent input parameters, the accuracy of the predicted results may be significantly improved compared to traditional predications from bit to surface. The auto-calibration method may tune the drilling hydraulic model for specific well region. It needs to point out that the hydraulic models are trained by using historical data from similar wells to insure its accuracy. Each sub-section in the meshed well has its own customized hydraulic model to increase the accuracy of the prediction.

The purpose of using the data-driven approach is to adjust the physics-based model so that it may be better adapted to the application conditions. During using the AI tuning algorithm (like Kalman Filter, but not limited to this algorithm), the model reciprocates between the prediction and update process, as shown in following figure (The physics-based models represent the drilling hydraulic model in this application). In this FIG. 8, functions f(xk, uk) is the prediction function; h(xk) is the relationship between prediction results and measurements, also called the update function; xk is the state vector, which contains the parameters we want to predict in the blind zone; yk is the measurement vector, which contains the data we may measure at surface or downhole; uk are control input into the system; wk and vk are the noise or uncertainties.

As illustrated in the above picture, it is illustration of the uncertainty handling. In the calculation, the well is divided into n number of cells, each cell has the pressure for this cell Pi. Assume the inlet of the flow is boundary condition, and the outlet is one of the measurements. Thus, the x vector has n−2 terms, and details of x vector is shown:

$${x}_{k} {=}^{△} [ \begin{matrix}\begin{matrix}\begin{matrix}\begin{matrix}{P}^{2} \\ …\end{matrix} \\ {P}^{i}\end{matrix} \\ …\end{matrix} \\ {P}^{n}\end{matrix} ]$$

The measurement vector yk is the measurements of pressure at the specific cells, where the pressure sensors located:

yₖ=hxₖ+vₖ

where h∈R^{2×3(n-2)}, subscript k is the time step, vₖ∈R² is the white noise.

The model automatically calibrate itself is to continuously compare the prediction results from a number of parallel cases (by using the uncertainty distribution of the inputs) with actual measurements. Thus, the uncertainties in inputs may be reduced and the prediction result become more accurate as the simulation continues.

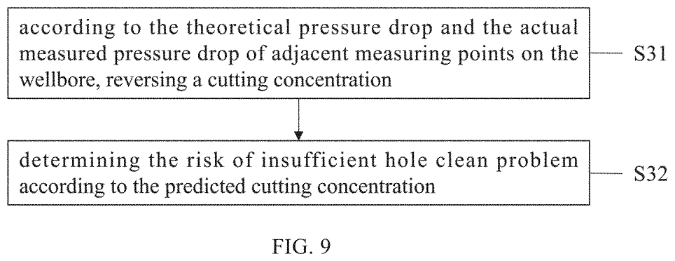

Refer to FIG. 9, step S23 specifically includes:

S31, relying on the theoretical pressure drop and actual measured pressure drop of adjacent measuring points on the wellbore, and reverse the cutting concentration;

S32, determining the risk of insufficient hole clean problem according to the predicted cutting concentration.

Among them, step S31 includes:

(1) comparing the ratio between the pressure drop values for flow with cuttings and without cuttings. The hydrostatic pressure is subtracted from the data and the solids effect factor on pressure loss, SF:

$$SF = \frac{Δ {P}_{c} - Δ {P}_{hyd}}{Δ {P}_{nc} - Δ {P}_{hyd}}$$

where ΔP_{c} is the pressure gradient with cuttings, ΔP_{nc} is the pressure gradient without cuttings, and ΔP_{hyd} is the hydrostatic pressure gradient for pure drilling fluid, and SF is the ratio between pressure loss caused by cuttings and the pressure loss caused by pure fluid flow at the same superficial fluid velocity; and

(2) establishing qualitative mathematic model to predict cutting concentration (Cc) by using SF and other input parameters. Like, wellbore geometry, inclination angle, fluid properties, also mean flow velocities. The purpose of the regression is to generalize and conclude the regularity contained in the data, and then establish qualitative mathematic model to predict Cc by using SF and other input parameters. One of the major problems for applying data-driven method is the shortage of labeled data. As the available useful data is limited, the use of data-driven methods based on large-scale data sets cannot achieve desired reliable results. Support vector machine algorithm has advantages in the conditions with small and nonlinear data sample sets. Therefore, SVM is chosen to train the data sets and generate the prediction model.

The basic algorithm of support vector (SVR) regression is to find the inner relationship between data points. By fitting the data at high latitudes, the algorithm may get a formula, and when a new input value is given, a new output value may be obtained. The biggest difference between SVR regression and traditional regression methods is: traditional regression methods require that the prediction is correct only if the returned f(x) is exactly equal to y, while SVR regression believes that when f(x) deviates from y, if the degree is within a certain range, the prediction is considered correct. The specific is to set a threshold value α and calculate the loss of data points with |f(x)−y|>α.

For the SVR model, the most important parameter is the type of kernel, which generally includes linear kernel, polynomial kernel, hyperbolic tangent kernel and gaussian radial basis function (rbf). In this work, the rbf is chosen as the kernel function. The parameters that mainly affect rbf include the penalty coefficient C and the kernel parameter γ.

In order to ensure the accuracy of the trained model, the cross-validation method is chosen to evaluate the reliability of the regressed model. Also, the cuttings concentration inversed from the pressure-driven hole cleaning model is compared to the results from traditional cuttings transport models, and a notification will be sent to users to request further analysis if the results from these two approaches are contradicted to each other.

The present disclosure provides a diagnose system of insufficient hole cleaning problem, including a processing unit and a memory unit. The memory unit stores computer program. The computer program when executed the processing unit, implements the method configured to assess the risk of insufficient hole clean problem.

The present disclosure provides a diagnose system of insufficient hole cleaning problem, including several along string measurement devices (ASMs) of using to measure annulus pressure in each measurement point.

The beneficial effects of present disclosure is: the theoretical pressure drop between two adjacent measurement points along wellbore includes the pressure drop caused by the friction effect and the hydrostatic effect. But, the suspended cuttings in actual drilling fluid may significantly change the pressure drop along wellbore. If there are a lot of cuttings, there will be a significant difference between the calculated and the measured pressure drop. Therefore, by comparing the relationship between the theoretical and the measured pressure drop, which may be configured to evaluate the insufficient hole cleaning problems and the problematic locations.

Finally, it should be noted that the above embodiments are only configured to illustrate the technical scheme of the present disclosure and not to restrict it. Notwithstanding the detailed description of the present disclosure by reference to the foregoing embodiments, the ordinary technical personnel in the field shall understand that it is still possible to modify the technical solutions recorded in the foregoing embodiments, or to equivalent replace some of the technical features thereof. However, these modifications or replacements do not remove the essence of the corresponding technical scheme from the spirit and scope of the technical scheme of each embodiment of the present disclosure.

What is claimed is:

1. A method for diagnosing the risk of insufficient hole cleaning problem, comprising:
obtaining measured pressure via each measuring point;
calculating theoretical pressure at each measuring point by using real-time operational data as input; and
evaluating a hole cleaning condition by applying a difference between the theoretical pressure and the measured pressure.

2. The method for diagnosing the risk of insufficient hole cleaning problem according to claim 1, comprising obtaining a theoretical pressure drop of two adjacent measuring points, comprising:
dividing wellbore information into several sections;
obtaining construction parameters and shape parameters of each well section, wherein the construction parameters comprise bit depth, well depth, drilling fluid density, average drilling fluid velocity, etc.;
calculating the theoretical pressure drop of each well section rely on the construction parameters and the shape parameters of each well section; and
obtaining the theoretical pressure drop of the two adjacent measuring points on the wellbore.

3. The method for diagnosing the risk of insufficient hole cleaning problem according to claim 2, comprising obtaining the theoretical pressure drop due to pressure drop caused by gravity effect and friction effect, comprising:
getting the pressure drop caused by the gravity effect due to the construction parameters and the shape parameters of each well section;
getting the pressure drop caused by the friction effect due to the construction parameters and the shape parameters of each well section;
and obtaining the theoretical pressure drop of each well section due to the pressure drop caused by the gravity effect and the friction effect.

4. The method for diagnosing the risk of insufficient hole cleaning problem according to claim 3, comprising obtaining the theoretical pressure drop caused by the gravity effect rely on the different construction parameters and the shape parameters of each well section, comprising:
using hydrostatic pressure method to calculate the pressure drop caused by the gravity effect.

5. The method for diagnosing the risk of insufficient hole cleaning problem according to claim 3, comprising obtaining the theoretical pressure drop caused by the friction effect rely on the different construction parameters and the shape parameters of each well section, comprising:
respectively determining a flow state of drilling fluid of each well section;
if the flow state of drilling fluid in a certain section is laminar flow, the pressure drop caused by the friction effect may be calculated according to a laminar flow annular air friction pressure loss model;
and if the flow state of the drilling fluid in the certain section is turbulent, the pressure drop caused by the friction effect maybe calculated according to a turbulent annular air friction pressure loss formula.

6. The method for diagnosing the risk of insufficient hole cleaning problem according to claim 5, comprising obtaining the theoretical pressure drop caused by the friction effect, wherein a pressure loss of the fluid flow in wellbore is obtained if there is turbulent flow:
$$Δ p = 2 {f}_{f} \frac{L}{{D}_{e}} ρ {v}^{2}$$
where f_{f} is a friction factor, L is a wellbore length, v is a mean flow velocity, ρ is a fluid density, and Dₑ is a equivalent diameter of the annulus.

7. The method for diagnosing the risk of insufficient hole cleaning problem according to claim 3, comprising obtaining the theoretical pressure drop which is equal to the friction effect and the gravity effect, comprising:
the theoretical pressure drop is equal to a sum of the pressure drop caused by the friction effect and the gravity effect in each well section.

8. The method for diagnosing the risk of insufficient hole cleaning problem according to claim 3, comprising determining the risk of insufficient hole clean problem due to the theoretical pressure drop and the measure pressure drop, comprising:
relying on the theoretical pressure drop and the actual measured pressure drop of adjacent measuring points on the wellbore, and reversing a cutting concentration;
and determining the risk of insufficient hole clean problem according to a predicted cutting concentration.

9. A device for diagnosing the risk of insufficient hole cleaning problem with along string measurement devices, comprising:
a processing unit; and
a memory unit;
wherein the memory unit stores computer program, and the computer program is executed by the processing unit to achieve the method for diagnosing the risk of insufficient hole clean problem according to claim 1.

10. A system for diagnosing the risk of insufficient hole cleaning problem with along string measurement devices according to claim 9, comprising: several along string measurement devices (ASMs) where the ASMs are arranged on each measuring point on the wellbore in a one-to-one correspondence manner and are configured to measure annulus pressure of each measurement point on the wellbore.
